(19) United States
(12) Patent Application Publication
(10) Pub. No.: US 2024/0266995 A1
(43) Pub. Date: Aug. 8, 2024

(54) PHOTOVOLTAIC COMPONENT

(71) Applicant: FOXLED1 AG, Hünenberg (CH)

(72) Inventor: Peter SCHIBLI, Hünenberg (CH)

(73) Assignee: FOXLED1 AG, Hünenberg (CH)

(21) Appl. No.: 18/011,015

(22) PCT Filed: Jun. 19, 2020
(86) PCT No.: PCT/EP2020/067130

§ 371 Date: Jun. 20, 2023

(51) Int. Cl. H02S 40/22; H02S 20/30; H02S 40/42

(52) U.S. Cl. CPC H02S 40/22; H02S 20/30; H02S 40/42

(57) ABSTRACT

The invention relates to a photovoltaic component (10) for applications outside the automotive sector, in particular for buildings, containers, boats, ships, construction vehicles, agricultural vehicles, trains and aircraft. The photovoltaic component has an outer pane (11) and an inner pane (12). Interposed between the outer pane (11) and the inner pane (12) is an energy generating layer (15) having a plurality of concentrator photovoltaic modules (20), the concentrator photovoltaic modules (20) having a condenser lens (21) as a primary optic and a photovoltaic chip (22) integrated into a surface mountable housing (30). The surface mountable housing (30) has at least two electrical contacts (22a, 22b) for contacting the photovoltaic chip (22), a transparent cover (36) and an integrated reflector (23) as secondary optics.

### FIELD OF INVENTION

The invention relates to a photovoltaic component for buildings, boats, ships, construction vehicles, agricultural vehicles, trains, aircrafts and other applications except automobiles. The invention further relates to buildings and devices having a photovoltaic component.

### BACKGROUND

Photovoltaics is the conversion of light energy, usually from sunlight, into electrical energy using solar cells or photovoltaic cells.

The concentrator photovoltaic uses lenses and/or reflectors to concentrate sunlight onto photovoltaic cells. This allows a reduction in cell size. The energy conversion is usually performed by a special high-performance solar cell, in particular by means of high-efficiency multi-junction solar cells made of, for example, III-V semiconductor materials.

Concentrator photovoltaic systems are categorized by the amount of their solar concentration, measured in “suns”. A distinction is made between low concentration systems, medium concentration systems and high concentration systems.

As a rule, increasing concentration also increases the complexity of the system. In particular, the requirements for cooling and optics increase.

Low-concentrator systems often have a simple booster reflector, but in some cases this can already increase solar electrical output by more than 30% over non-concentrator systems.

Highly concentrated systems, on the other hand, use more complex optical systems. These can consist, for example, of a Fresnel lens as the primary optic and a reflector as the secondary optic.

Solar mats are also known for 2-dimensional applications, which can be flexibly attached to various surfaces of buildings or devices. However, such solar mats, e.g. based on cadmium telluride or CIGS, have a limited efficiency.

Overall, it remains a challenge to integrate photovoltaic systems, especially concentrator photovoltaic systems, into buildings or devices in an efficient manner with high efficiency and to generate high solar output.

### DISCLOSURE OF THE INVENTION

It is therefore an object of embodiments of the present invention to provide a photovoltaic component for buildings, boats, ships, construction vehicles, agricultural vehicles, trains, aircrafts and other applications outside the automotive field, which avoids disadvantages of the known.

A further object of embodiments of the present invention is to provide a photovoltaic component that enables improved utilization of solar energy in buildings, boats, ships, construction vehicles, agricultural vehicles, trains, aircrafts, and other non-automotive applications, and in particular in a cost-effective and efficient manner and with advantageous efficiency.

A first aspect of the invention relates to a photovoltaic component according to claim 1.

Accordingly, the photovoltaic component has an outer pane and an inner pane. An energy generating layer comprising a plurality of concentrator photovoltaic modules is disposed between the outer pane and the inner pane. The concentrator photovoltaic modules have at least one condenser lens as the primary optics and a photovoltaic chip. The photovoltaic chip is integrated in a surface mountable housing. The surface mountable housing has at least two electrical contacts for contacting the photovoltaic chip, a transparent cover and an integrated reflector as secondary optics.

Such a photovoltaic component can be manufactured in an efficient and reliable manner. In addition, by integrating the energy-generating layer between the outer and inner panes, a long service life and reliability of the energy-generating layer can be achieved.

According to embodiments of the invention, concentrator photovoltaic modules are thus integrated into the photovoltaic component. This enables a high efficiency, especially compared to solar foils made of, for example, cadmium telluride.

The integration of the photovoltaic chip in a surface-mountable housing enables efficient (pre) production of the photovoltaic chip in very large quantities. At the same time, a reflector is already integrated into the chip's housing. Such surface mountable modules, which are also referred to as SMD-modules (surface mounted device), can be assembled and processed in a particularly efficient and automated manner. In particular, the surface-mountable housings with the integrated photovoltaic chips and the integrated reflectors can be efficiently applied to the respective carrier material of the respective application, e.g. to a carrier foil, by means of reflow soldering.

In solar operation, the condenser lens or collector lens, as the primary optics of the concentrator photovoltaic module, concentrates or collects incident sunlight through the first pane onto the transparent cover of the housing and the photovoltaic chip. The reflectors integrated into the housing act as the secondary optics of the concentrator photovoltaic module and operate as light collectors for the light transmitted from the condenser lenses. Thus, high efficiency can be realized in a manufacturing efficient manner.

The outer pane preferably has a high transmission. According to embodiments, the inner pane can also have a high transmission or a lower transmission than the outer pane.

According to an embodiment of the invention, the outer pane and/or the inner pane may be made of glass and thus be designed as a glass component. According to a further embodiment of the invention, the outer pane and/or the inner pane may consist of a plastic and thus be designed as a plastic component.

According to embodiments of the invention, a pane is generally used to designate sheet-like, in particular layer-like elements, which are in particular transparent or partially transparent. According to embodiments of the invention, a pane can thus also be referred to as a layer, in particular as a transparent or partially transparent layer. According to embodiments of the invention, a pane can have a wide variety of geometries adapted to the respective installation position. According to embodiments, a pane may in particular be rectangular or square. According to embodiments of the invention, a pane is in particular rigid or stiff.

According to a preferred embodiment of the invention, the photovoltaic component includes a reflective layer disposed below the energy generating layer. The reflective layer is configured to reflect sunlight incident through the first pane that has not yet been received by the concentrator photovoltaic modules.

This can further improve the efficiency of the concentrator photovoltaic module. According to embodiments, the reflective foil can be arranged between the energy generating layer and the inner pane or below the inner pane or the underside of the inner pane. Here, the terms “under” or “below” and “above” refer to the sun or the incident sunlight, respectively.

According to another preferred embodiment of the invention, the housing has a recess forming a receiving tray with a recessed bottom portion for receiving the photovoltaic chip, the receiving tray having side walls with reflective regions forming the reflector.

According to an embodiment, the receiving tray has sidewalls with at least a first reflective region and a second reflective region, wherein the first reflective region is oriented at a first angle relative to a horizontal plane of the housing and the second reflective region is oriented at a second angle relative to the horizontal plane of the housing. The first angle is thereby different from the second angle.

A concentrator photovoltaic module designed in this way makes it possible to select the two different angles of the first reflective region and the second reflective region individually and to adapt them to the respective external conditions, in particular the respective orientation of the surfaces intended for installation and the respective solar exposure of the surfaces intended for installation. The first and the second reflective region form reflective surfaces which receive the sunlight via the transparent cover, reflect it and transmit it in the direction of the photovoltaic chip or concentrate it on the photovoltaic chip. Thus, the at least two reflective regions of the receiving tray form a reflector.

It should be noted here that the term horizontal plane of the housing refers to the base or bottom plane of the housing and, in particular, is intended to run parallel to the bottom plane of the housing. The term horizontal plane of the housing is thus not necessarily intended to refer to the particular installation situation of the housing. For example, when the housing is installed vertically in a building, the horizontal plane of the housing may be perpendicular to the floor of the building.

According to embodiments of the invention, the angles of the different reflective regions can thus be individually adapted to the respective installation situation in the building. In particular, the angles of the reflective regions can be adapted in relation to the elevation and/or the azimuth.

The different angles of the first reflective region and the second reflective region can increase the concentrating or reflecting effect and the efficiency of the concentrator photovoltaic module and the photovoltaic component in a simple, cost-effective and efficient manner.

The transparent cover is preferably made of glass, in particular thin glass, e.g. Gorilla® glass or ultra-thin glass. According to another embodiment, the transparent cover can be made of plastic. According to preferred embodiments, the transparent or translucent cover allows the sunlight to pass as unhindered as possible into the reflector of the receiving tray and is therefore designed as a plane surface according to embodiments. In cross-section, the transparent cover is in particular rectangular, the thickness of the cover being selected to be as small as possible, for example 0.01 mm to 1 mm.

According to further embodiments, however, the transparent cover may also have a concave or convex shape and thus deflect and/or focus the sunlight.

According to embodiments, the photovoltaic chip can be designed as a single or as a multi-junction solar cell, in particular as a triple-junction or quadruple-junction solar cell. According to particularly preferred embodiments, the photovoltaic chip is a multijunction solar cell made of a III-V semiconductor material, e.g. gallium arsenide (GaAs) or gallium antimonide (GaSb). In particular, the photovoltaic chip is implemented as a photovoltaic DIE, i.e., an unhoused piece of a semiconductor wafer.

According to another advantageous embodiment of the invention, the photovoltaic component has a contact layer with conductor tracks for contacting the concentrator photovoltaic modules or the photovoltaic chip. The contact layer constitutes a printed circuit board or a carrier for the concentrator photovoltaic modules. The contact layer can be formed in particular as a coating on the pane or as a flexible foil.

According to an embodiment of the invention, the concentrator photovoltaic modules and the condenser lenses are integrated in a plastic material, in particular in a transparent plastic material.

According to another preferred embodiment of the invention, the energy-generating layer is integrated by means of an outer and an inner composite layer of plastic between the outer and the inner pane. The composite layer can advantageously be a plastic film, in particular made of PVB or EVA, or another plastic, e.g. PU or an acrylate or other plastic resin.

According to a preferred embodiment of the invention, the individual components of the photovoltaic component, in particular the surface-mountable housing, the concentrator photovoltaic modules and the contact layer, are transparent or largely transparent.

According to another advantageous embodiment of the invention, a heat-absorbing foil is arranged behind the energy-generating layer. This can, for example, reduce heating of the building interior.

According to another advantageous embodiment of the invention, a heat dissipating foil is arranged behind the energy generating layer. This can also reduce heating of the building interior as well as heating of the photovoltaic component.

The heat-absorbing foil and/or the heat-dissipating foil can be arranged in particular under the inner pane or between the inner pane and the energy-generating layer.

According to a further advantageous embodiment of the invention, the contact layer is designed as a heat-dissipating layer or foil. Here, in particular, the metallic conductor tracks can be used for heat dissipation.

According to another advantageous embodiment of the invention, the photovoltaic component comprises a middle pane arranged between the outer pane and the inner pane. Moreover, the energy generating layer is arranged as a first energy generating layer between the outer pane and the middle pane and a second energy generating layer is arranged between the middle pane and the inner pane. Thus, in such an arrangement, two levels of energy generating layers are provided. As a result, the solar energy produced can be increased.

In particular, the second energy generating layer may be horizontally offset from the concentrator photovoltaic modules of the second energy generating layer. This can further increase the solar energy produced.

According to an embodiment of the invention, the photovoltaic chip is arranged asymmetrically with respect to at least one vertical plane of symmetry of the housing. By means of such an asymmetrical arrangement of the photovoltaic chip in the housing, different angles of the first and the second reflective region can be realized particularly efficiently and space-saving in the housing.

According to another embodiment of the invention, the first and second reflective regions are opposite each other with respect to a first vertical plane of symmetry of the photovoltaic chip. In other words, the first and second reflective regions are arranged on opposite sides of the photovoltaic chip.

Such an embodiment with opposing reflective surfaces with different angles allows for improved concentration of sunlight on the photovoltaic chip, especially for sunlight that is not incident parallel to the first vertical plane of symmetry of the photovoltaic chip.

According to an embodiment of the invention, the first angle and the second angle differ from each other by at least 10°, in particular by at least 20°.

Such different angles are particularly advantageous if the solar radiation does not fall perpendicularly or symmetrically with respect to the perpendicular on the concentrator photovoltaic module. In such conditions, such different angles enable an improved optical concentrating effect of the reflector.

According to an embodiment of the invention, the first reflective region and the second reflective region are formed as a reflective coating of the receiving tray. According to embodiments, such a coating can be applied to a base body of the surface mountable housing, for example, by means of a corresponding coating process.

According to a further embodiment of the invention, the first reflective region and the second reflective region are formed as a reflective foil.

According to embodiments, such a reflective foil, e.g. a metal foil, can be applied to the base body made of plastic, e.g. by means of a corresponding adhesive process.

According to further embodiments of the invention, the receiving tray has sidewalls with a third reflective region and a fourth reflective region. The third reflective region is oriented at a third angle relative to the horizontal plane of the housing, and the fourth reflective region is oriented at a fourth angle relative to the horizontal plane of the housing. According to further embodiments, the third angle is different from the fourth angle.

Such embodiments thus have four different reflective regions or reflective surfaces, each of which may be oriented at individual and different angles with respect to the horizontal plane of the housing.

Up to four different angles of the reflector can be used for the light or solar radiation to further improve the concentration effect or reflection effect of the reflector.

Accordingly, photovoltaic components according to embodiments of the invention can be manufactured both for vertical installation surfaces, e.g. for vertical windows, and thus installation surfaces that are unfavorably aligned with respect to solar radiation, and for installation surfaces that are arranged almost horizontally, such as for roof surfaces.

According to an embodiment, the third angle and the fourth angle differ by at least 10°, in particular by at least 20°.

According to embodiments of the invention, the first angle, the second angle, the third angle and the fourth angle are in a range between 0° and 90°.

According to embodiments, the first angle can be in a range between 45° and 90°, in particular in a range between 60° and 75°, and the second angle can be in a range between 0° and 45°, in particular in a range between 10° and 35°. Such angles can be particularly advantageous for vertical installation situations.

According to embodiments of the invention, the housing is protected against solid foreign bodies and against liquids. According to embodiments, the housing has a scope of protection according to the International Protection (IP) code against solid foreign bodies of at least 5 and a scope of protection against liquids of at least 5. Such a protected housing ensures reliable and long-lasting operation even under adverse environmental conditions. In particular, the housing can be protected according to IP protection classes 65 to 68.

According to embodiments of the invention, the first reflective region, the second reflective region, the third reflective region and/or the fourth reflective region are each formed as a concave surface.

By means of such concave surfaces, the concentration effect of the reflective regions for the light or solar radiation can be increased.

According to other embodiments of the invention, the first reflective region, the second reflective region, the third reflective region, and/or the fourth reflective region are each formed as a planar surface.

This is particularly advantageous in terms of production technology.

According to embodiments of the invention, the housing has an integrated bypass diode, in particular a Schottky diode. The bypass diode can in particular be integrated into the base body, which can in particular be made of plastic. Such integration of the bypass diode in each individual housing results in particularly high reliability. If a photovoltaic chip is defective or not fully functional, the current can be diverted via the bypass diode and the functionality of the overall system is not or hardly affected.

Another aspect of the invention relates to a building or device having one or more photovoltaic components according to any one of the preceding claims.

In particular, the device may be a boat, a ship, a construction vehicle, an agricultural vehicle, a train, a container, or an aircraft.

Another aspect of the invention relates to the use of a photovoltaic component according to the above embodiments for installation in or attachment to a building, boat, ship, construction vehicle, agricultural vehicle, train, container, aircraft, and other devices excluding automobiles.

### BRIEF DESCRIPTION OF THE DRAWINGS

Further embodiments, advantages and applications of the invention result from the dependent claims and from the description now following by means of the basis of the figures. Thereby showing:

FIG. 1 a cross-sectional view of an energy-generating photovoltaic component according to an embodiment of the invention;

FIG. 2 a cross-sectional view of an energy-generating photovoltaic component according to another embodiment of the invention;

FIG. 3 a cross-sectional view of an energy-generating photovoltaic component according to another embodiment of the invention;

FIG. 4 a cross-sectional view of an energy-generating photovoltaic component according to another embodiment of the invention;

FIG. 5 a cross-sectional view of a concentrator photovoltaic module according to an embodiment of the invention;

FIG. 6a a cross-sectional view of a concentrator photovoltaic module in a x-z plane;

FIG. 6b a cross-sectional view of the concentrator photovoltaic module 20 in a y-z plane;

FIG. 6c a top view of the concentrator photovoltaic module in the x-y plane;

FIG. 7 a cross-sectional view of a concentrator photovoltaic module with electrical contacts;

FIG. 8a a photovoltaic component for predominantly horizontal installation in a device;

FIG. 8b a photovoltaic component with an inclined mounting position;

FIG. 8c a photovoltaic component for a predominantly vertical installation in a device;

FIG. 9 a top view of a photovoltaic chip array;

FIG. 10 a lens array according to an embodiment of the invention having a plurality of condenser lenses arranged in a plane;

FIG. 11 shows a side view of a building or house with photovoltaic components;

FIG. 12 shows a top view of the building of FIG. 11;

FIG. 13 shows a side view of a house with a flat roof;

FIG. 14 shows an aircraft with multiple photovoltaic components integrated into the outer skin of the aircraft; and

FIG. 15 shows a ship with several photovoltaic components arranged on the surface of the ship.

### WAY(S) TO CARRY OUT THE INVENTION

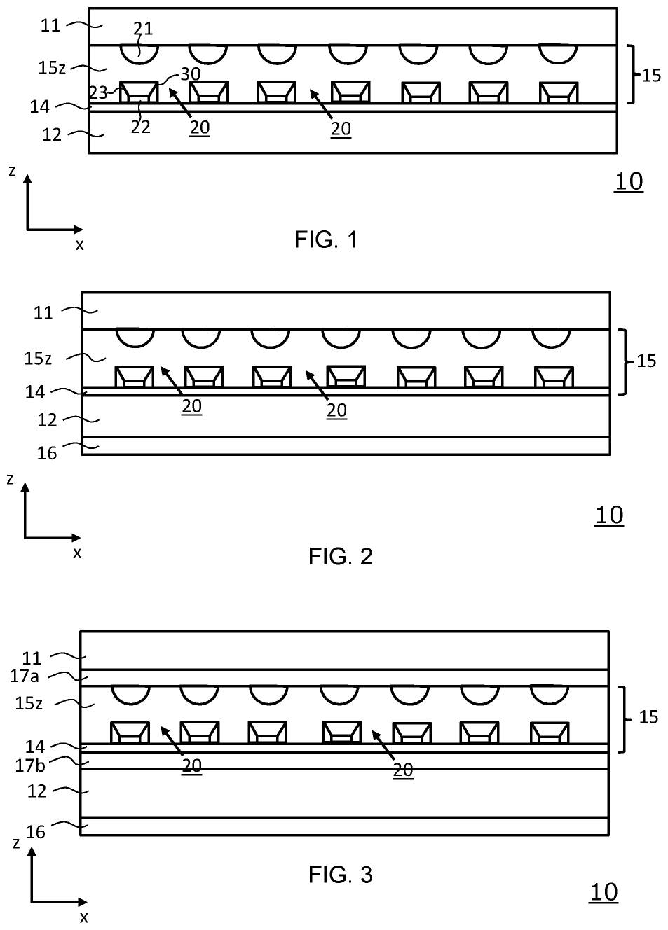

FIG. 1 shows a cross-sectional view of an energy generating photovoltaic component 10 in an x-z plane according to an embodiment of the invention. The energy generating photovoltaic component 10 has an outer pane 11 and an inner pane 12. According to embodiments, the outer pane 11 and the inner pane 12 may be made of glass or of plastic. The outer pane 11 preferably has a high transmission in the desired wavelength range and may in particular be a clear glass pane or a non-coloured plastic pane. According to embodiments, the inner pane 12 can also be designed with high transmission. According to other embodiments, the inner pane 12 may have a lower transmission than the outer pane 11. In particular, the inner pane 12 may be designed as tinted glass or coloured plastic.

According to embodiments of the invention, the outer pane 11 and the inner pane 12 may be made of glass, such as soda-lime silicate glass, borosilicate glass, aluminosilicate glass, or plastic, such as polycarbonate or PMMA. According to embodiments of the invention, the outer pane 11 and the inner pane 12 may have different thicknesses, and the outer glass pane 11 and the inner glass pane 12 may be designed with or without thermal or chemical bias. According to an embodiment, both the first pane and the second pane may be made of glass. According to another embodiment, the first pane may be made of glass and the second pane may be made of plastic. According to another embodiment, the second pane may be made of glass and the first pane may be made of plastic. According to an embodiment, both the first pane and the second pane may be made of plastic.

An energy generating layer 15 is provided between the outer pane 11 and the inner pane 12. The energy generating layer 15 has a plurality of concentrator photovoltaic modules 20. The concentrator photovoltaic modules 20 each have a condenser lens or converging lens 21 and a photovoltaic chip 22 integrated into a surface mountable housing 30. The condenser lens 21 is configured to focus and direct incident sunlight onto the photovoltaic chip 30 or a transparent cover of the housing 30. The condenser lens 21 acts as the primary optics of the concentrator photovoltaic module 20, and a reflector 23 integrated into the housing 30 acts as a light collector or collector and collects the light incident on the transparent cover of the housing 30. Such two-stage optics can significantly increase the efficiency of the photovoltaic chips 22.

The energy-generating layer 15 comprises a contact layer 14 with conductor tracks. The contact layer 14 can be formed, for example, as a printed circuit board, in particular as a flexible printed circuit board, and in particular as a flexible as well as transparent foil. The contact foil 14 may be formed as a heat dissipating film.

The surface mountable housings 30 can be arranged on the contact layer 14 by soldering, in particular by reflow soldering, and electrically connected to the photovoltaic chips 22.

According to embodiments of the invention, the energy generating layer 15 or the interstices 15z of the energy generating layer 15 may be filled with transparent plastic. According to other embodiments of the invention, the energy-generating layer 15 or the interstices 15z of the energy-generating layer 15 can be formed as a vacuum.

FIG. 2 shows a cross-sectional view of an energy-generating photovoltaic component 10 in an x-z plane according to a further embodiment of the invention. The photovoltaic component 10 corresponds to a large extent to the photovoltaic component 10 of FIG. 1. In addition, the photovoltaic component 10 has a reflective layer 16, which is arranged below the energy-generating layer 15. In this context, the terms “below” and “above” are to be understood in relation to the sun and the direction of incident sunlight, respectively, in the present description. The reflective layer 16 is configured to reflect sunlight incident through the first pane 11 that has not yet been received by the concentrator photovoltaic modules 20 and converted into electrical energy. The sunlight thus reflected can then be received by the concentrator photovoltaic modules 20 after all through further reflection or scattering, for example, through reflection or scattering by the outer pane 11. This may further increase the efficiency. According to another embodiment of the invention, the reflective layer 16 can also be arranged between the inner pane 12 and the energy generating layer 15.

FIG. 3 shows a cross-sectional view in an x-z plane of an energy generating photovoltaic component 10 according to a further embodiment of the invention. The photovoltaic component 10 corresponds to a large extent to the photovoltaic component 10 of FIG. 2. According to the embodiment of FIG. 3, the energy generating layer 15 is integrated between the outer pane 11 and the inner pane 12 by means of an outer composite layer 17a and an inner composite layer 17b. The composite layers 17a, 17b can be formed in particular as lamination foils and can be made of plastic, e.g. PVB or EVA. Such composite layers facilitate the manufacturing of the energy-generating photovoltaic component.

FIG. 4 shows a cross-sectional view of an energy generating photovoltaic component 10 according to another embodiment of the invention. Initially, the photovoltaic component 10 has the components shown in FIG. 1, namely an outer pane 11, an inner pane 12, an energy generating layer, and a contact layer 14.

In addition, the photovoltaic component 10 has a middle pane 13 disposed between the outer pane 11 and the inner pane 12. According to this embodiment of the invention, the photovoltaic component 10 has two energy generating layers, namely a first energy generating layer 15a between the outer pane 11 and the middle pane 13 and a second energy generating layer 15b between the middle pane 13 and the inner pane 12. Both the energy generating layer 15a and the energy generating layer 15b have a plurality of concentrator photovoltaic modules 20. According to an advantageous embodiment of the invention, the concentrator photovoltaic modules 20 of the layer 15a are horizontally offset from the concentrator photovoltaic modules 20 of the layer 15b. In particular, the concentrator photovoltaic modules 20 of the lower second energy generating layer 15b are arranged in the horizontal spaces between the upper first energy generating layer 15a. This allows sunlight not received by the concentrator photovoltaic modules 20 of the first layer 15a to be collected by means of the concentrator photovoltaic modules 20 of the second layer 15b arranged thereunder. This can further increase the efficiency.

According to a further embodiment of the invention, the photovoltaic components 10 may also have further layers, in particular foils. Thus, according to embodiments of the invention, a heat-absorbing foil or a heat-dissipating foil can be arranged behind or below the energy-generating layer 15. According to embodiments of the invention, the reflective layer 16 can be replaced by a heat-absorbing foil or a heat-dissipating foil, or a heat-absorbing or heat-dissipating foil can additionally be provided.

According to embodiments, the foils can be transparent or partially transparent and applied as a lamination foil. According to embodiments, the photovoltaic components 10 can be provided with an anti-scratch coating in the case of plastic and/or a low-E coating in the case of glass.

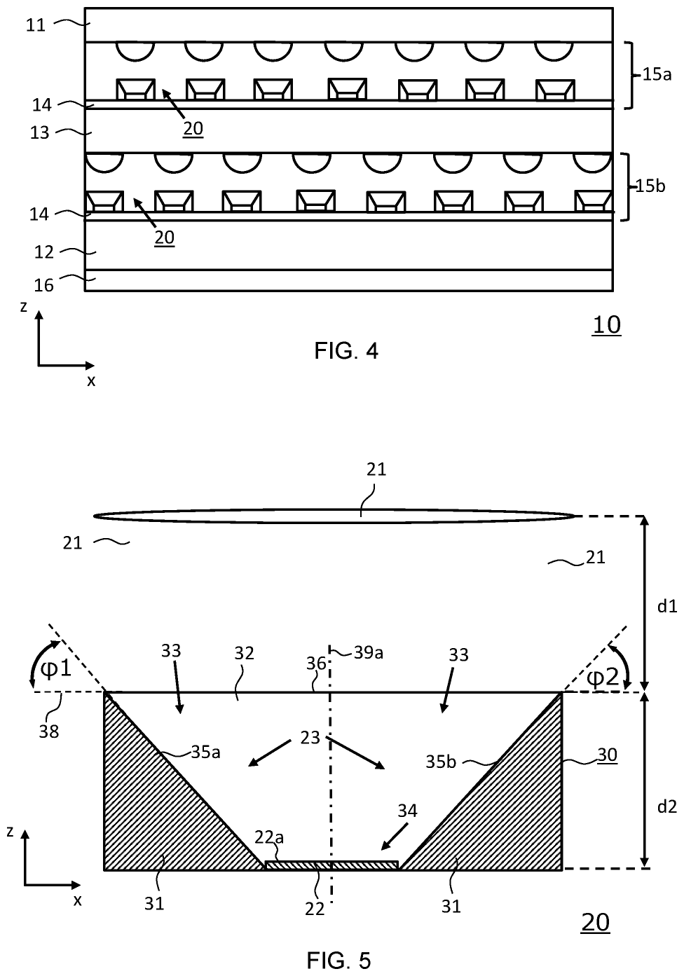

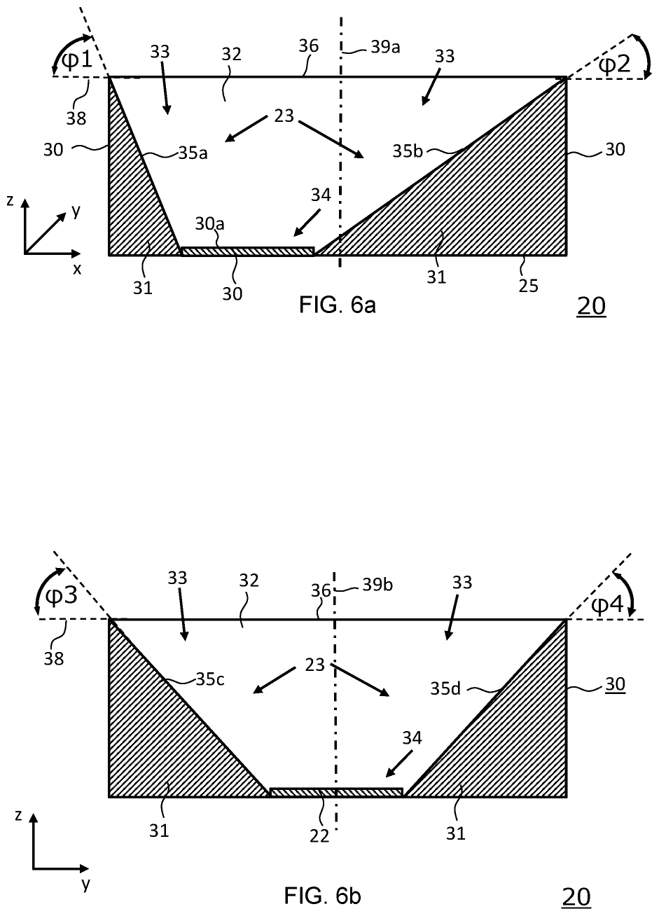

FIG. 5 shows a cross-sectional view of a concentrator photovoltaic module 20 in a x-z plane according to an embodiment of the invention. According to this embodiment, the photovoltaic chip 22 is arranged symmetrically with respect to a vertical plane of symmetry 39a of the housing 30.

The concentrator photovoltaic module 20 has a lens 21 designed as a condenser lens or converging lens as the primary optic for focusing sunlight. The lens 21 is located at a predefined distance d1 from the housing 30. The height of the housing 30 is denoted by d2.

The housing 30 comprises a base body 31. The base body 31 can be made in particular of plastic and can be produced, for example, by means of an injection moulding process. The housing 30 or the base body 31 has a recess 32. The recess 32 forms or establishes a receiving tray 33 with a recessed bottom portion 34 for receiving the photovoltaic chip 22. According to preferred embodiments of the invention, the photovoltaic chip 22 is designed as a multi-junction solar cell, but according to other embodiments of the invention, it can also be designed as a single-junction solar cell. According to embodiments of the invention, a photovoltaic chip means in particular a photovoltaic DIE, i.e. an unhoused piece of a semiconductor wafer with a multi-junction or single-junction solar cell.

The concentrator photovoltaic module 20 has at least two electrical contacts for contacting the photovoltaic chip 22, which are not shown in FIG. 5 to simplify the illustration. The concentrator photovoltaic module 20 further comprises a transparent cover 36 which closes the housing 30 and in particular the recess 32, in particular seals it in a waterproof and dustproof manner.

According to embodiments, the transparent cover 36 is made of glass, in particular thin glass or ultra-thin glass. Preferably, the housing 30 is protected against solid foreign bodies and against liquids by means of the transparent cover 36. For this purpose, housing 36 may be designed in particular in accordance with IP protection class 66. According to embodiments, housing 36 has a scope of protection according to the International Protection (IP) code against solid foreign bodies of at least 4 and a scope of protection against liquids of at least 4. The transparent cover 36 can be attached to the housing 30, in particular to the base body 31, by means of ultrasonic welding, for example.

The receiving tray 33 includes side walls having reflective regions 35a and 35b. The receiving tray 33 forms a reflector 23 by means of the reflective regions. The reflector 23 constitutes a secondary optic of the concentrator photovoltaic module 20 and is configured to function as a light collector or optical homogenizer. According to embodiments, the reflector 23 may be a conical cylinder or a conical cuboid.

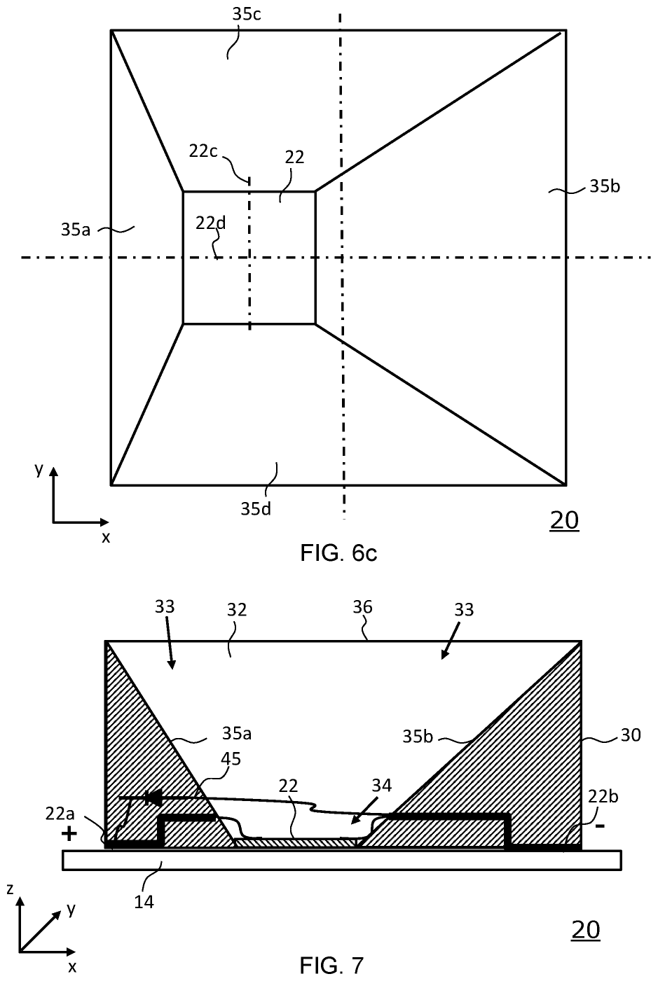

FIG. 6a shows a cross-sectional view of a concentrator photovoltaic module 20 in a x-z plane according to another embodiment of the invention. FIG. 6b shows a cross-sectional view of the concentrator photovoltaic module 20 in a y-z plane perpendicular to the x-z plane. FIG. 6c shows a top view of the concentrator photovoltaic module 20 in the x-y plane.

In FIGS. 6a to 6c, the primary optics with the condenser lens 21 is not shown for simplicity of illustration.

The concentrator photovoltaic module 20 is similar in construction to the module shown in FIG. 5, and accordingly includes a housing 30 having a base body 31 and a recess 32 forming a receiving tray 33 with a recessed bottom portion 34 for receiving the photovoltaic chip 22.

The receiving tray 33 includes sidewalls having a first reflective region 35a, a second reflective region 35b, a third reflective region 35c, and a fourth reflective region 35d. The first reflective region 35a is oriented at a first angle φ1 with respect to a horizontal x-y plane 38 of the housing 30. The second reflective region 35b is oriented at a second angle φ2 with respect to the horizontal x-y plane 38 of the housing 30. The third reflective region 35c is oriented at a third angle 93 with respect to the horizontal x-y plane 38 of the housing 10. The fourth reflective region 35d is oriented at a fourth angle φ4 with respect to the horizontal x-y plane 38 of the housing. According to the embodiment illustrated in FIGS. 6a to 6c, the first angle φ1 is different from the second angle φ2, while the third angle φ3 and the fourth angle φ4 are equal or approximately equal in this example. According to other embodiments, the third angle φ3 and the fourth angle φ4 may also be of different sizes.

In particular, as shown in FIGS. 6a and 6b, the photovoltaic chip 22 is arranged asymmetrically with respect to the vertical plane of symmetry 39a of the housing 30, while it is arranged symmetrically with respect to the vertical plane of symmetry 39b of the housing 30.

As can be seen in particular from FIGS. 6a and 6c, the first reflective region 35a and the second reflective region 35b are opposite to each other with respect to the photovoltaic chip 22, in particular with respect to a first vertical plane of symmetry 22c of the photovoltaic chip 22 shown in FIG. 1c.

According to the example shown, the first angle φ1 is approximately 65° and the second angle φ2 is approximately 35°.

According to embodiments of the invention, the angles φ1, φ2, φ3 and φ4 is in a range between 0° and 90°. According to preferred embodiments of the invention, the first angle φ1 is in a range between 45° and 90°, in particular in a range between 60° and 75°, and is thus relatively steep, while the second angle φ2 is in a range between 0° and 45°, in particular in a range between 10° and 35°, and is thus relatively flat.

Such an embodiment is advantageous, for example, for photovoltaic modules intended for vertical installation. This makes it possible to significantly improve the power yield of the photovoltaic module when installed vertically, in particular because the “lower” reflective surface is more inclined with respect to the horizontal plane of the housing than the “upper” reflective surface.

According to embodiments, the first reflective region 35a, the second reflective region 35b, the third reflective region 35c, and the fourth reflective region 35d are applied as a coating to the base body 31 of the receiving tray 33.

According to other embodiments, the first reflective region 35a, the second reflective region 35b, the third reflective region 35c and the fourth reflective region 35d are formed as a reflective foil, which can be applied to the base body 31 of the receiving tray 33, for example, by means of adhesive or other processes.

According to the embodiments shown in FIGS. 6a to 6c, the reflective regions 35a, 35b, 35c and 35d are each designed as planar surfaces, in particular as trapezoidal surfaces.

However, according to other embodiments not shown, the reflective regions 35a, 35b, 35c, and 35d may have other shapes, particularly concave shapes and convex shapes.

A module designed in this way allows the angles φ1, φ2, φ3 and φ4 of the reflective regions 35a 35b, 35c and 35d to be selected individually and differently in each case and to be adapted to the respective orientation of the modules to the surfaces intended for installation and the corresponding solar exposure of the modules in terms of elevation and/or azimuth.

FIG. 7 shows a cross-sectional view of a concentrator photovoltaic module 20 in an x-z plane according to an embodiment of the invention. In FIG. 7, the electrical connections of the module are shown in more detail. In particular, the concentrator photovoltaic module 20 has a first electrical contact 22a and a second electrical contact 22b. The electrical contacts 22a, 22b are arranged on opposite sides of the housing 30 and are formed as so-called leads, which are embedded in the base body 31 made of plastic. The photovoltaic chip 22 is electrically connected to the leads of the electrical contacts 22a and 22b by means of wire bonding. Thus, the module 20 is formed as a surface mountable module in SMD-technology (Surface Mount Technology). The module 20 also has a bypass diode 45 integrated into the housing 30, which can be designed in particular as a Schottky diode. The bypass diode is connected in parallel with the photovoltaic chip 22 and accordingly connected on the one hand to the electrical contact 22a and on the other hand to the electrical contact 22b, also according to embodiments by means of wire bonding. The photovoltaic chip 22 can, for example, be electrically contacted with conductor tracks of the contact layer 14 by means of soldering.

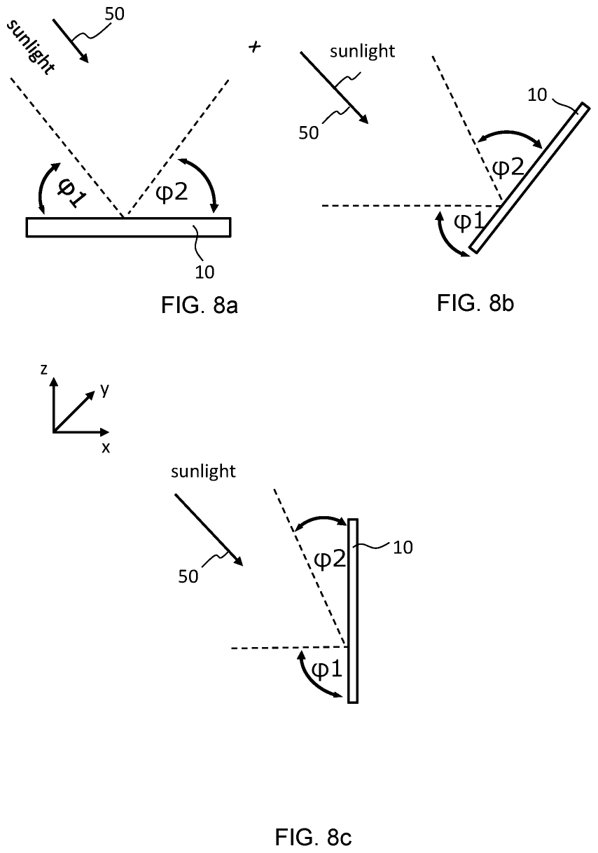

FIGS. 8a to 8c show various installation situations of photovoltaic components 10 and the surface-mountable housings integrated therein. The angles φ1 and φ2 refer to the angles of the reflection surfaces of the reflectors integrated in the housings 30.

In FIGS. 8a to 8c, the position of the sun 50 is shown in an exemplary manner, e.g. at the noon time.

In addition, FIGS. 8a to 8c show the course of the reflective surfaces of the reflectors 23 in an exemplary manner by means of dashed lines.

FIG. 8a shows a photovoltaic component 10 intended for predominantly horizontal installation in a building or device, for example as a horizontal roof photovoltaic component. FIG. 8b shows a photovoltaic component 10 intended for inclined installation positions, for example between 20° and 80°, e.g. for pitched roofs.

FIG. 8c shows a photovoltaic component 10 intended for primarily vertical installation in a building or device.

According to embodiments of the invention, the first angle φ1 and the second angle φ2 can each be individually adapted to the respective installation situation in order to optimize the light capture of the reflector for the respective installation situation. While the first angle φ1 and the second angle φ2 are preferably selected to be the same size for a horizontal installation, the first angle φ1 and the second angle φ2 are preferably selected differently for an inclined and a vertical installation situation in order to increase the light capture with respect to the elevation of the solar radiation.

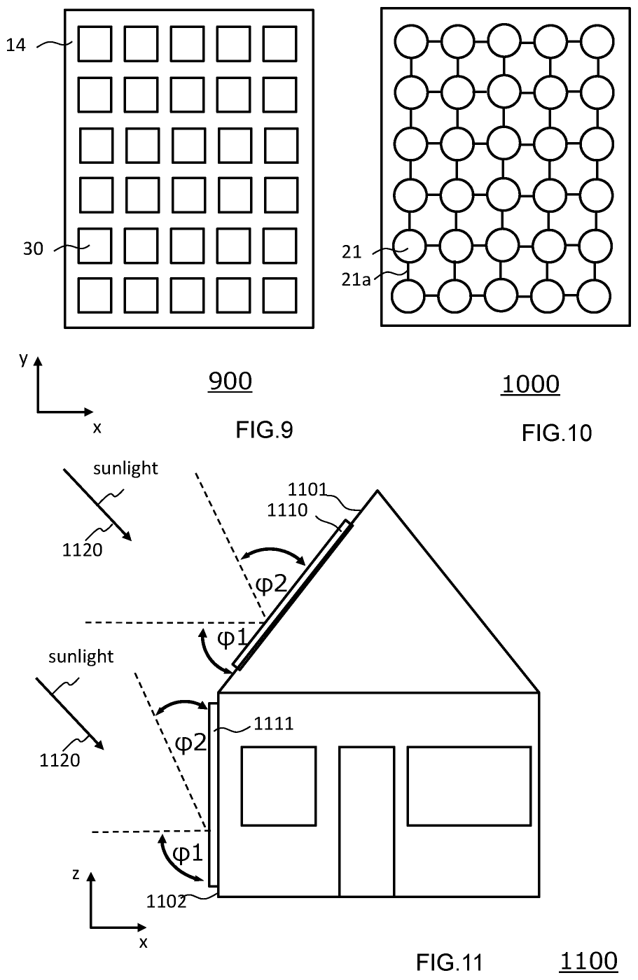

FIG. 9 shows a top view of a photovoltaic chip array 900. The photovoltaic chip array 900 has a plurality of SMD housings 30 with integrated photovoltaic chips and reflectors, which are soldered as surface-mounted components on a printed circuit board or contact layer 14 formed as a foil.

FIG. 10 shows a lens array 1000 according to an embodiment of the invention with a plurality of condenser lenses 21 arranged flatly in a plane. The lens array 1300 can be prefabricated, for example, by injection moulding from transparent plastic. The individual condenser lenses 21 are connected by thin webs 21a. According to an embodiment, the lens array prefabricated in this way can be attached to the underside of the outer pane 11, e.g. by adhesive bonding. According to another embodiment, the prefabricated lens array 1100 may first be attached to the photovoltaic chip array 1200 and then attached between the panes.

FIG. 11 shows a side view of a building or house 1100. The building 1100 has a photovoltaic component 1110 on an inclined roof 1101 and a photovoltaic component 1111 on a vertical side wall 1102, which may be configured like the photovoltaic components 10 described above.

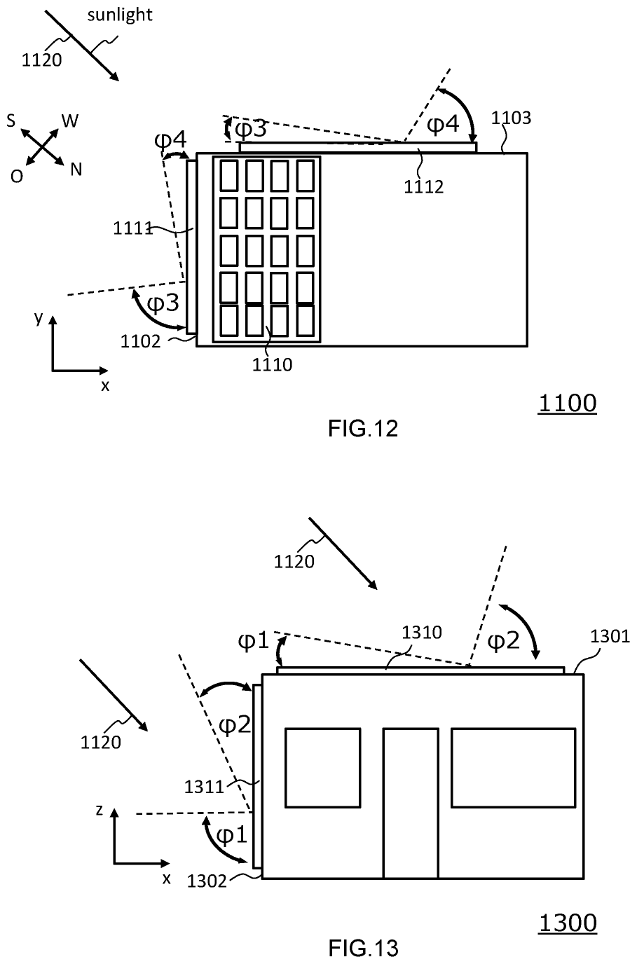

FIG. 12 shows a top view of the building 1100, showing that in addition to the photovoltaic component 1110 and the photovoltaic component 1111, the building 1100 has another photovoltaic component 1112 on the back wall 1103.

In particular, the photovoltaic components 1110, 1111, and 1112 may be formed as shown in the top view of FIG. 9.

In FIGS. 11 and 12, the position of the sun 1120 is shown in an exemplary manner, for example, at the noon time.

In addition, in FIG. 11, the first angle φ1 and the second angle φ2 of the individual photovoltaic components 1110 and 1111 are shown in an exemplary manner by means of dashed lines.

Furthermore, in FIG. 12, the third angle 93 and the fourth angle φ4 of the individual photovoltaic components 1110 and 1112 are shown in an exemplary manner by means of dashed lines.

The angles φ1, φ2, φ3 and φ4 again refer to the angles of the reflection surfaces of the reflectors of the concentrator photovoltaic modules of the individual photovoltaic components integrated into the housings 30.

In the example of FIGS. 11 and 12, the individual photovoltaic components 1110, 1111 and 1112 each have different combinations of the individual angles φ1, φ2, φ3 and φ4. This makes it possible to take into account the respective installation situation of the systems 1110, 1111 and 1112 and to optimally adapt the angles φ1, φ2, φ3 and φ4 to the position of the sun or the course of the sun in order to achieve a maximum concentration effect or amplification of the reflector.

According to embodiments of the invention, the first angle φ1 and the second angle φ2 are selected in particular so that they optimally take into account the respective installation situation with respect to the elevation of the sun.

According to embodiments of the invention, the third angle φ3 and the fourth angle φ4 are in particular selected in such a way that they optimally take into account the respective installation situation with respect to the azimuth of the sun. Thus, FIG. 12 also shows the orientation of the house with respect to the cardinal directions. Exemplarily, the house wall 1102 has a southeast exposure and the back wall 1103 has a southwest exposure. By appropriately and individually choosing the angles φ3 and φ4 for the side wall 1102 and the back wall 1103, the efficiency of the photovoltaic component can be improved.

FIG. 13 shows a side view of a house 1300 with a flat roof 1301. A photovoltaic component 1310 is mounted on the flat roof 1301 and a photovoltaic component 1311 is mounted on a vertical side wall 1302.

The first angle 1 and the second angle φ2 of the photovoltaic component 1310 are selected differently from the first angle φ1 and the second angle φ2 of the photovoltaic component 1110 of the inclined roof shown in FIG. 11 to improve the reflectivity of the photovoltaic components.

Thus, according to embodiments of the invention, the photovoltaic components 10 can be used as energy-generating glass or plastic components for roof systems, flat roofs, industrial roofs, house roofs, facades, facade constructions, and/or as single or multi-pane insulating glasses.

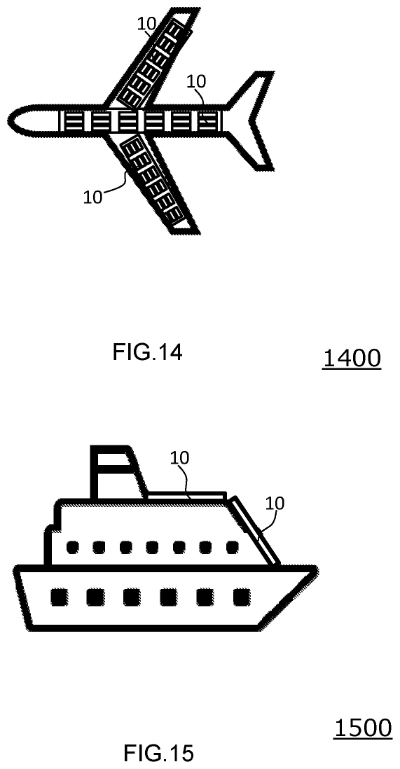

FIG. 14 shows an aircraft 1400 with multiple photovoltaic components (10) integrated into the outer skin of the aircraft 1400.

FIG. 15 shows a ship 1500 with a plurality of photovoltaic components (10) disposed on the surface of the ship.

According to further embodiments of the invention, the photovoltaic components (10) may also be integrated or attached to construction vehicles, agricultural vehicles, trains or containers.

While preferred embodiments of the invention are described in the present application, it should be clearly noted that the invention is not limited to these and may be carried out in other ways as well within the scope of the following claims.

1. Photovoltaic component (10) for buildings, containers, boats, ships, construction vehicles, agricultural vehicles, trains, aircrafts and other applications except automobiles, comprising,
an outer pane (11); and
an inner pane (12);
characterized in that
an energy generating layer (15) comprising a plurality of concentrator photovoltaic modules (20) is disposed between the outer pane (11) and the inner pane (12), wherein the concentrator photovoltaic modules (20) comprise at least one condenser lens (21) as primary optics and a photovoltaic chip (22) integrated in a surface mountable housing (30), the surface mountable housing (30) having at least two electrical contacts (22a, 22b) for contacting the photovoltaic chip (22), a transparent cover (36) and an integrated reflector (23) as secondary optics.

2. Photovoltaic component according to claim 1, wherein the photovoltaic component (10) comprises a reflective layer (16) disposed below the energy generating layer (15) and configured to reflect sunlight incident through the first pane (11) that has not yet been received by the concentrator photovoltaic modules (20).

3. Photovoltaic component according to claim 1 or 2, characterized in that the housing (30) has a recess (32) forming a receiving tray (33) with a recessed bottom portion (34) for receiving the photovoltaic chip (22), wherein
the receiving tray (33) has side walls with reflective regions (35a, 35b) which form the reflector (23).

4. Photovoltaic component according to claim 3, characterized in that
the receiving tray (33) has sidewalls with at least first and second reflective regions (35a, 35b), the first reflective region (35a) being oriented at a first angle (φ1) with respect to a horizontal plane (38) of the housing (30) and the second reflective region (35b) being oriented at a second angle (φ2) with respect to the horizontal plane (38) of the housing (30); and
the first angle (φ1) is different from the second angle (φ2).

5. Photovoltaic component according to claim 4, wherein the receiving tray (33) comprises side walls with a third and a fourth reflective region (35c, 35d), wherein the third reflective region (35c) is oriented at a third angle (φ3) with respect to the horizontal plane of the housing (30) and the fourth reflective region (35d) is oriented at a fourth angle (φ4) with respect to the horizontal plane of the housing (30), in particular wherein the third angle is different from the fourth angle.

6. Photovoltaic component according to claim 1, wherein the photovoltaic component (10) comprises a contact layer (14) with conductor tracks for contacting the concentrator photovoltaic modules (20).

7. Photovoltaic component according to claim 1, wherein the concentrator photovoltaic modules (20) are integrated into a plastic material.

8. Photovoltaic component according to claim 1, wherein the energy generating layer (15) is integrated between the outer and inner panes by means of an outer and an inner composite layer (17a, 17b) of plastic material.

9. Photovoltaic component according to claim 8, wherein the outer composite layer and/or the inner composite layer (17a, 17b) is a plastic film, in particular of PVB or EVA.

10. Photovoltaic component according to claim 1, characterized in that a heat-absorbing foil (16) is arranged behind the energy-generating layer (15) or a heat-dissipating foil (16) is arranged behind the energy-generating layer (15).

11. (canceled)

12. Photovoltaic component according to claim 6, characterized in that the contact layer (14) is designed as a heat-dissipating foil.

13. Photovoltaic component according to claim 1, characterized in that the photovoltaic component comprises a middle pane (13) arranged between the outer pane and the inner pane, wherein the energy generating layer is arranged as a first energy generating layer (15a) between the outer pane (11) and the middle pane (13), and a second energy generating layer (15b) comprising a plurality of concentrator photovoltaic modules (20) is arranged between the middle pane (13) and the inner pane (12).

14. Photovoltaic component according to claim 13, characterized in that the concentrator photovoltaic modules (20) of the second energy generating layer (15b) are horizontally offset from the concentrator photovoltaic modules of the first energy generating layer (15a).

15. Photovoltaic component according to claim 1, characterized in that the housing (30) has an integrated bypass diode (45), in particular a Schottky diode.

16. Photovoltaic component according to claim 1, characterized in that the photovoltaic chip (22) is a multi-junction solar cell, in particular a multi-junction solar cell made of a III-V semiconductor material.

17. Photovoltaic component according to claim 1, characterized in that the outer pane (11) and the inner pane (12) are made of glass or of plastic.

18. Photovoltaic component according to claim 1, characterized in that the photovoltaic component is designed as an energy-generating component for roof systems, flat roofs, industrial roofs, house roofs, facades, facade structures and/or as single or multiple insulating glass for buildings.

19. Building with one or more photovoltaic components (10) according to claim 1.

20. Device comprising one or more photovoltaic components (10) according to claim 1, wherein the device is a boat, a ship, a construction vehicle, an agricultural vehicle, a train, a container or an aircraft.

21. Use of a photovoltaic component according to claim 1 for installation in or attachment to a building, boat, ship, construction vehicle, agricultural vehicle, train, container, or aircraft, and other devices excluding automobiles.
